(19) United States
(12) Patent Application Publication
(10) Pub. No.: US 2011/0226317 A1
(43) Pub. Date: Sep. 22, 2011

(54) Surface Plasmon Resonance Enhanced Solar Cell Structure with Broad Spectral and Angular Bandwidth and Polarization Insensitivity

(76) Inventors: Fang Xu, San Diego, CA (US); Lin Pang, San Diego, CA (US)

(21) Appl. No.: 12/729,201

(22) Filed: Mar. 22, 2010

(51) Int. Cl. H01L 31/00; H01L 31/18

(52) U.S. Cl. 136/255; 136/256; 438/88

(57) ABSTRACT

Disclosed is an active layer electrically contacted to a first electrode, the first electrode being configured for SPR when interacting with light, said configuration being an array of nanostructures with a space varying periodicity and orientation so that SPR thereon is less affected by the spectral wavelength, angle, and/or polarization of the incident light. Related methods are further disclosed.

### CROSS-REFERENCE TO RELATED APPLICATIONS

N/A

### STATEMENT REGARDING FEDERALLY SPONSORED RESEARCH OR DEVELOPMENT

N/A

### BACKGROUND OF THE INVENTION

1. Field of Invention

The present invention is in the field of apparatus and methods for converting solar radiation into electrical energy.

2. Background of the Invention

Solar radiation represents a free, environmentally clean, and virtually inexhaustible source of energy. In its natural state, solar energy has limited utility in regard to satisfying the energy needs of modern human populations. Furthermore, other, more conventional energy sources, e.g., fossil fuels, are thought to be of finite and non-renewable amounts (non-renewable energies). For these reasons, much effort has been directed toward converting solar energy into states which are more readily exploitable or utilizable by humankind.

Electrical energy is a form of energy with universal applications and which is heavily relied on by humankind. In recent history, apparatus have become known, and have been successfully implemented, which convert solar radiation into electrical energy according to the photovoltaic effect. Such devices are known as photovoltaic (“PV”) solar cells.

A typical PV solar cell operates by receiving sun light on an electric conversion unit or active layer. Active layers have typically been a semi-conductor having a p-n junction (typically bulk silicon substrates including single crystalline, polycrystalline, and amorphous silicon substrates) to produce electron-hole pairs or excitons whenever illuminated with light. In operation, each electron and hole of produced exciton pairs are pulled in opposite directions by the internal electric field of the p-n junction resulting in an electric current. The same effect in organic cells is accomplished via either a bilayer of acceptor and donor materials or a bulk heterojunction of an acceptor and donor material. The resultant electric current may be extracted by electrodes and delivered to an electric circuit or an electricity storage device.

Despite this successful development and implementation, PV solar cell technologies have not yet been completely satisfactory for their intended purpose since: (1) manufacturing costs are high and efficiencies are too low for PV solar technologies to compete with non-renewable energies in terms of costs per energy watt produced; (2) there are not viable long-term energy storage options for electricity produced by the solar technologies; (3) manufacturing of the active layer produces large amounts of toxic waste; and, (4) solar technologies have typically been large, bulky, and, therefore, hard to install. Accordingly, there is a need for apparatus and methods for converting solar radiation into electrical energy in a manner which improves upon apparatus and methods heretofore known for the same purpose.

To address some of the above-identified drawbacks, apparatus have been designed with a thinner active layer, typically on the order of one to two micrometers. Manufacturing costs and production of toxic waste are reduced by thinning the active layer since less of the expensive semiconducting materials are required to be purchased or produced. Bulkiness is also reduced by employing a thinner active layer. However, despite the identified improvements, thin active layer PV solar technologies operate at less efficiency than PV technologies with a relatively thick active layer since the light penetrating a thin active layer may more readily pass therethrough without being absorbed to produce excitons (i.e., without producing electricity). Accordingly, there is a need for improved apparatus and methods for converting solar radiation into electrical energy.

To increase light absorption and electricity production efficiency, light trapping designs have been developed whereby the light is retained within the active layer for a longer period of time. Notably, back surface reflection has been employed to increase the amount of light absorbed by thin active layers by re-directing unabsorbed light into the active layer and by using front surface anti-reflection to increase the amount of light reaching the active layer. See, e.g., U.S. Pat. No. 4,493,942 (issued Jan. 15, 1985). Nevertheless, efficiencies remain low, for example, the efficiencies of organic thin film solar cells are less than ten-percent.

Recently, it has been discovered that surface plasmon polariton (SPP) assisted solar technologies may be developed to result in enhanced electricity production due to surface resonant excitation or surface plasmon resonance (SPR). SPPs are oscillating electromagnetic fields that propagate along the surface of a metal and dielectric. SPR is the resonant interaction of light with the SPP to produce enhancements or excitements in the SPP (i.e., in the oscillating electric fields). Typically, SPP assisted solar cell designs have included metallic nanoparticles, metallic nanofilms or slits, nano-wires, or the like that are illuminated to produce SPR thereon. See, e.g., U.S. Pat. No. 4,482,778 (issued Nov. 13, 1984) and U.S. Pat. No. 6,441,298 (issued Aug. 27, 2002). SPP assisted PV cells have heretofore operated by using the enhanced electrical fields produced by the SPR to either (1) be directly converted to electricity (see U.S. Pat. No. 4,482,778) or (2) concentrate the light onto an active layer (see U.S. Pat. No. 6,441,298, col. 4:61-65).

Although SPP assisted solar technologies are an advancement over previously known solar technologies, SPP excitation is not fully understood whereby SPP assisted solar technologies can be further improved from their present state. In particular, presently known SPP assisted solar cells do not absorb the full range of spectral widths associated with black body radiation; and, the full range of the incident angles of solar radiation which are caused by the earth's rotation. Furthermore, the electric field produced by SPR has not been provided to a PV active layer to increase the relative electric field and thereby increase the exciton generation rate of the active layer. Finally, the electric field produced by SPR has not yet been successfully provided to a PV active layer with back surface reflection, front surface anti-reflection, and in a manner that is less affected by the spectral and angular bandwidth or polarization of the incident light. For these reasons, there is still a need for solar cell technologies that effectively use SPR to enhance existing solar to electric conversion.

### SUMMARY OF THE INVENTION

It is an object of the present application to disclose apparatus and related methods for efficiently converting solar radiation into electricity in a manner that improves upon apparatus and methods heretofore known for the same purpose.

It is yet a further object of the present application to provide an apparatus and related methods for efficiently converting solar radiation into electricity despite large spectral and angular variation in solar illumination.

It is yet still an object of this invention to provide an apparatus and related method for efficiently converting solar radiation into electricity wherein the conversion efficiency in thin film (organic or inorganic) active layers is measurably increased.

It is yet another object of the present application to meet the aforementioned needs without any of the drawbacks associated with apparatus heretofore known for the same purpose. It is yet still a further objective to meet these needs in an efficient and inexpensive manner.

In one non-limiting embodiment, a preferred apparatus is a PV solar cell comprising: an active layer electrically contacted to a first electrode and a second electrode; the first electrode being configured for SPR when interacting with light, said configuration being an array of metallodielectric nanostructures, said array being configured with a space varying periodicity and orientation whereby SPR thereon is less affected by the spectral wavelength, angle, and polarization and/or orientation of the incident light; the first electrode further featuring an upper surface topography that is nonreflective (i.e., anti-reflective); the second electrode being electrically conductive (metallic or graphite) and featuring locally positioned metallic nanostructures disposed thereon whereby the SPR at the first electrode may produce localized SPR at the metallic nanostructures; and, wherein the first and second electrodes form a Fabry-Perot cavity around the active layer.

### BRIEF DESCRIPTION OF THE FIGURES

The manner in which these objectives and other desirable characteristics can be obtained is better explained in the following description and attached figures in which:

FIG. 1 is a perspective view of an apparatus 1 embodying the present disclosure.

FIG. 2 is an exploded perspective view of the apparatus of FIG. 1.

FIG. 3 is a perspective view of an electrode 200 having an array of nanostructures with space varying periodicity and orientation.

It is to be noted, however, that the appended figures illustrate only typical embodiments disclosed in this application, and therefore, are not to be considered limiting of its scope, for the invention may admit to other equally effective embodiments that will be appreciated by those reasonably skilled in the relevant arts. Also, figures are not necessarily made to scale.

### DETAILED DESCRIPTION OF PREFFERED EMBODIMENTS

In general, a preferred embodiment of the present disclosure is a surface plasmon resonance enhanced solar cell structure with broad spectral and angular bandwidth and polarization insensitivity. As with ordinary solar cell structures, the preferred embodiment may generally feature a photovoltaic charge producing (i.e., active) material sandwiched between electrodes for extracting photo-induced charges. However, unlike traditional solar cell structures, the presently disclosed embodiment may feature subwavelength metallodielectric structures that are simultaneously the upper electrode of the solar cell, as well as an SPP supplier. In such a configuration, the electrode suitably, among other things: (1) interacts with incident light to enhance the electric field at the active layer via SPR; (2) extracts charges generated by the active layer; and (3) features a topography which provides an anti-reflection surface to the solar cell. Further, the presently disclosed embodiment may also feature localized nanostructures provided to the lower electrode whereby coupling from the propagating SPP produced at the upper electrode may preferably excite the localized SPR at the nanostructures to further enhance the electric field at the active layer. The enhanced electric field at the active interface suitably increases the efficiency of the active material since the light absorption and exciton creation therein strongly depends on the power spectral density and square relative electric field of the incident light. Finally, the presence of the upper and lower electrodes may further increase the efficiency of the preferred solar cell by trapping light within the active layer via creating a Fabry-Perot cavity around the active layer (i.e., light will be trapped in the active layer as the electrodes function as opposing mirrors). The more specific aspects of the preferred embodiment are best disclosed by referencing the figures.

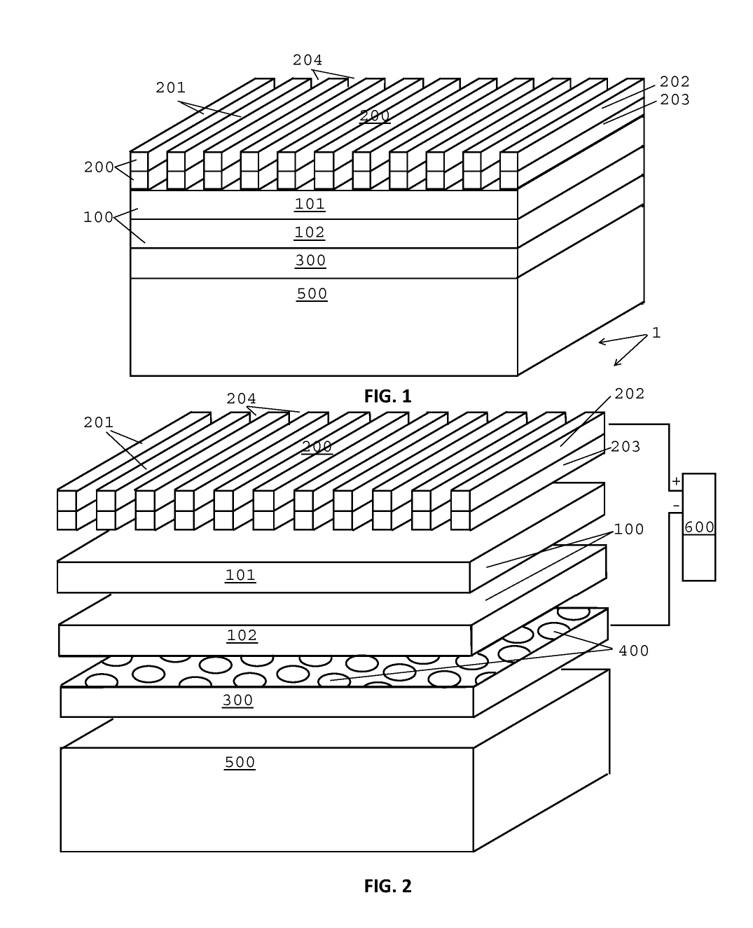

FIG. 1 is a three-dimensional perspective view of an a solar cell apparatus 1 defining a preferred embodiment of a surface plasmon resonance enhanced solar cell structure with broad spectral and angular bandwidth and polarization insensitivity. FIG. 2 is a three-dimensional exploded view of the apparatus of FIG. 1. Referring to the recited figures, the apparatus 1 is generally comprised of: a photovoltaic charge producing material (i.e., active material or active layer) 100; an upper electrode 200; a lower electrode 300 featuring localized nanostructures 400 disposed thereon; and a support substrate 500. Please note: although disclosed in terms of a “top” and “bottom” surface or “lower” and “upper”, the terms “top,” “bottom,” “upper,” or “lower” or any other orientation defining term should in no way be construed as limiting of the possible orientations of the apparatus 1 (i.e., the apparatus 1 may be positioned sideways, or in reversed vertical orientations even though the specification refers to a “top” and “bottom” side). Taken together, FIGS. 1 and 2 suitably illustrate the above referenced components of the depicted apparatus 1.

Referring to FIGS. 1 and 2, the active material 100 preferably defines a thin-layered p-n type photo diode centrally disposed within the apparatus 1. In other words, the active material 100 suitably features a first layer 101 of n-doped material and a second layer 102 of p-doped material whereby the layers are coupled to form a p-n junction that is suitably capable of photovoltaically producing an electric charge (electron-hole pair or excitons) when illuminated. As discussed further below, the active material 100 may be electrically contacted to the upper 200 and lower 300 electrodes whereby the active material 100 may communicate the produced electrical charges to an electric circuit 600.

It should be noted that, in alternate embodiments, the active material 100 may preferably be comprised of organic or inorganic donor 102 and acceptor 101 layers or a bulk heterojunction (blend) of organic/inorganic donor and acceptor materials (101 and 102). For organic active layers 100 it is preferable that a PDOT:PSS buffer be disposed between the organic material and the lower electrode 200. Those skilled in the art will know well the organic and inorganic donor and acceptor materials that are suitable for use in the present application.

Operably, a primary function of the active layer 100 is the production of electricity from sunlight. Suitably, illuminating the active layer 100 with light will result in charge creation according to the photovoltaic effect as the light (i.e., photons) passes therethrough. In regards to the active layer 100, many materials are known to those of skill in the art which will produce excitons when illuminated with light, and include but are not limited to: silicon including single crystalline, polycrystalline, and amorphous silicon; a nanostructured bulk heterojunction of the electron acceptor (p-type) 3,4,9,10perylene tetracarboxylic bisbenzimidazole (PTCBI) and donor (n-type) copper phthalocyanine (CuPc); or a CuPc/PTCBI bilayer. Preferably, the electrical charges may be extracted from the active layer 100 and delivered to an electric circuit 600 via the upper 200 and lower 300 electrodes.

Referring still to FIGS. 1 and 2, the upper electrode 200 is typically a patterned array of nanostructures 201 electrically contacted to the n-side 101 of the active material 100. The patterned array of nanostructures 201 are preferably compositely defined by at least one layer of metallic material 202 and at least one layer of dielectric material 203. A suitable metal may be, but is not limited to, silver, gold, copper, titanium, or chromium. A suitable dielectric may be silicon dioxide, or titanium dioxide. In the present embodiment, the nanostructures 201 are variously spaced to generally define slits 204 between nanostructures 201. In addition to conducting electric charges away from the active layer 100, the upper electrode 200 features other functionalities.

First, the electrode enhances the active layer 100 via SPR. The exciton generation rate of the active layer 100 is strongly dependant on, among other things, the electric field incident to the active layer. Specifically, exciton generation of the active layer, G(z,ω,θ), is given by:

G_{s,p}(z,ω,θ)=((n_{N}(ω)*α_{N}(ω))/(n₁(ω)*h*ω))*|(ω,θ)*abs(E_{s,p}(z,ω,θ))̂2

Where: |(ω,θ) is the incident solar power spectral density per unit projected area as a function of azimuthal angle, θ; E_{s,p}(z,ω,θ) is the relative electric field with respect to the incident electric field; and n and a are the real part of the refractive index and absorption coefficient respectively, of the different layers of the active layer. See M. Agrawal and P. Peumans, “Broadband optical absorption enhancement through coherent light trapping in thin-film photovoltaic cells,” Optics Exp. 6, 5385 (2008). As the light interacts with the upper electrode 200, SPR results in an electric field being provided to the active layer 100 which correspondingly increases its exciton generation. Yet still, the electric field produced via the SPR may further induce localized SPR on the localized nanostructures 400 to produce additional electric fields being incident to the active layer 100, which electric fields correspondingly increase the exciton generation rate of the active layer 100. In this manner the efficiency of the active layer 100 is increased.

Second, the upper electrode 200, being a patterned array of nanostructures 201, may preferably act as a subwavelength grating (i.e., the period (distance between slits 204) of the electrode 200 is less than half the wavelength of light) wherein the slits 204 operate as the grooves of the grating for enhancing SPP excitation or SPR. As alluded to above, SPP excitation at the electrode 200 by light depends on, among other things, (1) the wavelength and incident angle of the light and (2) the grating period. Specifically, SPP excitation parameters can be determined by:

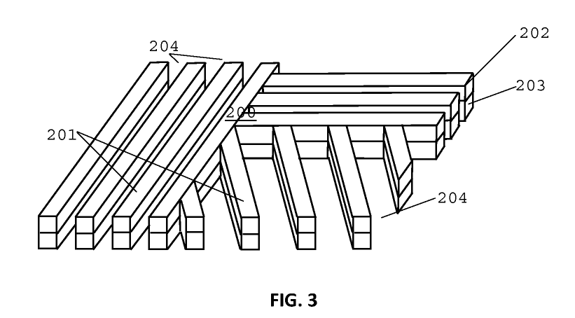

(ε_{d}*εₘ/(ε_{d}+εₘ))̂½=abs(sin(θ)+λ/d)

where: ε_{d} is the refractive index of the dielectric in the nanostructure 201; εₘ is the refractive index of the metal in the nanostructure 201; θ is the incident angle necessary for SPP excitation; λ is the wavelength necessary for SPP excitation; and d is the grating period. In the context of sun light, the spectral distribution and incident angle at a given point on earth change as the earth rotates whereby a grating of fixed period would be non functional in terms of SPR on a stationary grating unless the incident parameters and grating period satisfy the above-identified relationship. For this reason, the electrode 200 configuration of the present embodiment may preferably be of space varying periodicity (i.e., the period of the grating will change for different locations over the surface of the active layer 100) and space varying orientation (i.e., the orientation of the grating grooves will change for different locations over the surface of the active layer 100) in order that SPR occurs regardless of the natural condition of the incident light. In other words, changing the grating period and/or orientation of the grating at different spatial locations over the array of nanostructures 201 will ensure that at SPR is occurring at some point on the electrode 200 regardless of the natural condition of the sunlight (e.g., an SPR enhanced active layer with broad spectral and angular bandwidth and polarization insensitivity). A non-limiting example of an electrode 200 having an array of nanostructures 201 with space varying periodicity and space varying orientation may be seen in FIG. 3. It should be noted: although the spacing is preferably subwavelength and the spacing and orientation of the electrode 200 depicted herein this application should in no way be construed as limiting of the possible spacing and orientation that may be implemented within an embodiment of this disclosure. On the contrary, any spacing and orientation may be implemented without departing from the purposes and intents of this disclosure.

Third, again referring to FIGS. 1 and 2, another function of the electrode 200 is to mitigate the amount of light which is reflected off of the apparatus prior to interacting with the active layer 100. As set forth above, ordinary solar cells are known to reflect away a percentage of incident light that would otherwise be converted to electricity if allowed to interact with the cells' active layer. The topography, configuration, and composition of the composite metallodielectric patterned nanostructures 201 of the upper electrode 200 result in an upper surface with a negative refractive index. Such a topography, configuration, and composition can be obtained and accomplished according to R. C. Tyan, A. A. Salvekar, H. P. Chou, C. C. Cheng, A. Scherer, P. C. Sun, F. Xu, and Y. Fainman, “Design, fabrication, and characterization of form-birefringent multilayer polarizing beam splitter,” J. Opt. Soc. Am. A 14, 1627 (1997) while also accounting for the other functions of the electrode 200. This feature of the present disclosure permits more light to interact with the active layer 100 whereby efficiency of the solar cell is improved.

As seen in FIG. 2, the electrode 300 is preferably a layer of metallic material with metallic nanostructures 400. Operably, the electrode 300 is preferably contacted with the p-side of the active layer 100 in electrical communication. The nanostructures 400 are preferably nanometer sized metallic structures arrayed over the surface of the electrode 300. In addition to conducting electric charges away from the active layer 100, the electrode 300 features other functionalities.

First, as mentioned above, the localized nanostructures 400 on the surface of the electrode 300 suitably couple with the electric field generated by SPR on the upper electrode 200 whereby localized SPR occurs on the localized nanostructures. The additional electric fields produced by the localized SPR preferably further enhance the exciton generating capacity of the active layer 100 in accordance with the principles outlined above.

Second, the upper 200 and lower 400 electrodes cooperate to trap light within the active layer 100 whereby a larger percentage of incident light is absorbed by the active layer 100 and thereby converted to electricity. As alluded to above, light may not be photovoltaically absorbed by the active layer 100 upon its initial incidence whenever the light absorption length is greater than the thickness of the active layer. In such a circumstance, the metallic properties of the upper 200 and lower 300 electrodes preferably operate to trap light within the active layer 100 in the manner of a Fabry-Perot cavity. In other words, light is preferably reflected back and forth through the active layer 100 between the upper 200 and lower 400 metallic electrodes until its absorption therein. In this manner, the efficiency of the solar cell apparatus 1 is improved.

The support 500 is any generic item on which the other components of the apparatus may be retained. Such items are well known to those of skill in the art.

It should be noted that FIGS. 1 through 3 and the associated description are of illustrative importance only. In other words, the depiction and descriptions of the present application should not be construed as limiting of the subject matter in this application. For example, thicknesses of the active layer 100 or spacing and orientation of the nanostructures 201 and 400 may be readily changed and altered without departing from the purposes and intents of this application. Additional modifications may become apparent to one skilled in the art after reading this disclosure.

I claim:

1. A photovoltaic cell comprising:
an active layer electrically contacted to a first electrode and a second electrode, the first electrode being configured for SPR when interacting with light, said configuration being an array of nanostructures, said array being configured with a space varying periodicity and orientation whereby SPR thereon is less affected by the spectral wavelength, angle, and/or polarization of the incident light.

2. The apparatus of claim 1 wherein the first electrode further features an upper surface topography that is anti-reflective.

3. The apparatus of claim 1 wherein the second electrode is electrically conductive and features locally positioned metallic nanostructures disposed thereon whereby the SPR at the first electrode may produce localized SPR at the metallic nanostructures.

4. The apparatus of claim 1 wherein the first and second electrodes form a Fabry-Perot cavity around the active layer.

5. The apparatus of claim 1 wherein the active layer is comprised of a layer of n-doped material and a layer of p-doped material, the layers coupled to form a p-n junction.

6. The apparatus of claim 1 wherein the active layer is a nanostructured organic or inorganic thin film.

7. The apparatus of claim 1 wherein the nanostructures of the first electrode are a metallodielectric.

8. The apparatus of claim 1 wherein the nanostructures of the first electrode comprise at least one layer of metallic material and at least one layer of dielectric material.

9. A method of increasing the exciton generation rate of the active layer in a solar panel, comprising the steps of
obtaining an active layer
contacting the active layer with a first electrode comprising an array of array of nanostructures, said array being configured with a space varying periodicity and orientation whereby SPR thereon is less affected by the spectral wavelength, angle, and/or polarization of the incident light;
applying the electric field produced by the SPR to the active layer to increase its exciton generation rate.
illuminating the electrode and the active layer.

10. The method of claim 9 wherein the first electrode further features an upper surface topography that is anti-reflective.

11. The method of claim 9 wherein the active layer is contacted to a second electrode that features locally positioned metallic nanostructures disposed thereon whereby the SPR at the first electrode may produce localized SPR at the metallic nanostructures.

12. The method of claim 11 further comprising the step of positioning the first and second electrodes to form a Fabry-Perot cavity around the active layer.

13. The method of claim 12 wherein the active layer is comprised of a layer of n-doped material and a layer of p-doped material, the layers coupled to form a p-n junction.

14. The method of claim 12 wherein the active layer is a nanostructured organic or inorganic thin film.

15. The method of claim 12 wherein the nanostructures of the first electrode are a metallodielectric.

16. The method of claim 11 wherein the nanostructures of the first electrode comprise at least one layer of metallic material and at least one layer of dielectric material.

17. A photovoltaic cell comprising:
an active layer electrically contacted to a first electrode and a second electrode;
the first electrode being configured for SPR when interacting with light, said configuration being an array of metallodielectric nanostructures, said array being configured with a space varying periodicity and orientation whereby SPR thereon is less affected by the spectral wavelength, angle and/or polarization of the incident light;
the first electrode further featuring an upper surface topography that is anti-reflective;
the second electrode being metallic and featuring locally positioned metallic nanostructures disposed thereon whereby the SPR at the first electrode may produce localized SPR at the metallic nanostructures; and,
wherein the first and second electrodes form a Fabry-Perot cavity around the active layer.

18. The apparatus of claim 17 wherein the active layer is comprised of a layer of n-doped material and a layer of p-doped material, the layers coupled to form a p-n junction.

19. The apparatus of claim 17 wherein the nanostructures of the first electrode comprise at least one layer of metallic material and at least one layer of dielectric material.

20. The apparatus of claim 12 wherein the nanostructures of the first electrode are a metallodielectric.
